(19) United States
(12) Patent Application Publication
(10) Pub. No.: US 2009/0301610 A1
(43) Pub. Date: Dec. 10, 2009

(54) Process for depositing a thin film of metal alloy on a substrate and metal alloy in thin-film form

(75) Inventors: Pascale Gillon, Olivet (FR); Anne-Lise Thomann, Menestreau-en-Villette (FR); Pascal Brualt, Saint Denis En Val (FR)

Correspondence Address: Pepper Hamilton LLP, 400 Berwyn Park, 899 Cassatt Road, Berwyn, PA, 19312-1183, US

(73) Assignee: UNIVERSITE D'ORLEANS, Orleans (FR)

(21) Appl. No.: 12/440,259

(22) PCT Filed: Sep. 10, 2007
(86) PCT No.: PCT/EP2007/059487

§ 371 Date: Jul. 24, 2009

(30) Foreign Application Priority Data
Sep. 8, 2006 (FR) 06/07876

(51) Int. Cl. C22C 45/00; C23C 14/35

(52) U.S. Cl. 148/403; 204/192.15

(57) ABSTRACT

The present invention relates to a process for depositing a thin film of a metal alloy on a substrate, said film comprising at least four components and said alloy being either: an amorphous alloy containing 50 at % of the elements Ti and Zr, or a high-entropy alloy, the elements of which are chosen from the group consisting of Al, Co, Cr, Cu, Fe, Ni, Si, Mn, Mo, V, Zr and Ti; by simultaneous magnetron sputtering of at least two targets. The present invention also relates to a metal alloy in the form of a thin film comprising at least four components, which can be deposited on a substrate by implementing the process.

The invention relates to a process for depositing on a substrate a thin film of metal alloy and to novel metal alloys able to be deposited on a substrate by applying the process.

The formation of amorphs (or glasses) in metal systems is very difficult because of the high atomic mobility in metals, which promotes crystallization. This is why metal amorphs (A. Inoue, Bulk Amorphous Alloys, Materials Science Foundations, Vol. 6, 1999) have to be prepared by fast solidification, which limits the thickness of the parts (less than 0.2 mm for strips). In the years 1980-1990, novel alloys were discovered which have a larger vitrification capacity (Zr—Ti—Cu—Ni—Be, Ti—Zr—Cu—Ni—Be, Zr—Ti—Al—Cu—Ni), and which provide access to bulk amorphous metal parts, the smallest dimension of which may attain 20 or even 30 mm.

These novel materials are of high interest because they have remarkable properties both on a mechanical level, since they are both hard and ductile, and in corrosion resistance (no grain boundaries), or even in terms of transport properties (thermal, electric conductivity, . . . ) or surface properties. However these exceptional properties are only retained at operating temperatures below that of crystallization (around 500° C.). Moreover, the elaboration and especially the shaping of these alloys, are more delicate actually because of their properties. They consist of relatively costly elements and have high density. In order to overcome these drawbacks, and for certain applications, it is interesting to produce deposits of metal amorphs rather than to use a bulk part.

Other alloys recently discovered and consisting of a number of elements comprised between 5 and 13, and for which the atomic percentage of the main elements does not exceed 35% (known as high entropy alloys) are also of high interest from the point of view of their properties. Consisting of solid solutions and having a nanostructured phase (nanocrystalline precipitate in an amorphous or crystalline matrix), certain compositions exhibit very large hardnesses and a temperature strength above 1,000° C. (Multi-principal-element alloys with improved oxidation and wear resistance for thermal spray coating, Ping-Kang HUANG, Jien-Wien YEH, Tao-Tsung SHUN and Swe-Kai CHEN, Advanced Engineering Materials 2004, 6, No. 1-2, p. 74).

These high entropy alloys have better heat stability than zirconium(Zr)-based amorphous metal alloys, a larger hardness (130-1,100 Hv—Vickers hardness index) than conventional alloys and better resistance to corrosion.

These high entropy alloys have physical characteristics which make them potential candidates in all technical applications where large hardness, wear and oxidation resistance, good chemical inertia are required at high temperature. Thus, these alloys may be used for coating and making metal parts, parts used in the chemical industry, and functional coatings (anti-adhesive surfaces, surfaces having tribological properties).

Further, these high entropy alloys have good resistance to wear (similar to that of ferrous alloys of same hardness). Additionally most of these alloys have good corrosion resistance (as good as that of stainless steels; notably when they contain elements such as Cu, Ti, Cr, Ni or Co), excellent resistance to oxidation (up to 1,100° C.; notably when they contain elements such as Cr or Al) (nanostructured High-Entropy Alloys with multiple principal elements: novel alloy concepts and outcomes; Jien-Wei Yeh et al., Advanced Engineering Materials 2004, 6, No. 5).

Studies have shown the possibility of making deposits of metal amorphs of composition Zr Al Cu Ni and Zr Ti Al Cu Ni by cathode sputtering from bulk targets of the alloy of the composition (Plasma sputtering of an alloyed target for the synthesis of Zr-based metallic glass thin films, A. L. Thomann, M. Pavius, P. Brault, P. Gillon, T. Sauvage, P. Andreazza, A. Pineau). A similar process may be used for making high entropy alloy deposits. But for this, it is necessary to pass through a step for elaborating the target either from elements by melting, casting and cutting, or by hot compression of powders. In both cases, there is no means of modifying the composition of the deposit without passing again through a step for elaborating a new target.

Deposition of films (lead-zirconium-titanium) on a Pt/Ti/Si/SiO₂ substrate in a magnetron-rf sputtering reactor from a metal target with several elements has also been described (S. Kalpat and K. Uchino, highly oriented lead zirconium titanate thin films: growth, control of texture and its effect on dielectric properties, Journal of Applied Physics, Vol. 92, No. 6, pp 2703-2710). It was thereby shown that the use of a metal target with several elements has many advantages because it provides interesting possibilities (such as high deposition rates) and that it is easy to change the composition of the target by adding or suppressing pieces of Pb—Zr—Ti in order to obtain the desired stoichiometry. The designed target is a disc consisting of several alternating sectors of Pb, Ti, Zr forming a circular target. They have shown that the composition of the films for i elements may be provided by using the following equation

Xi=[(Yi*Ai*100/ΣYi*Ai)] (1)

wherein

Yi: is the sputtering rate of element i.

Ai: is the sector of element i.

In the case of the use of a single multi-element target, once the target is made up, the composition of the deposited alloy is set. In order to change the composition of this alloy (during a process or subsequently), it is necessary to change the geometry (number and size of the portions) of the target. To do this, a new target should be elaborated. Further, if the targeted alloy comprises a strongly predominant element, a target designed by using equation (1) will be unbalanced (the surface of the other elements entering the composition of the final deposit will be small or even unachievable particularly in the case of elements, the proportion of which in the deposit is low and for which the sputtering rate is high) and it will not be possible to attain the targeted composition.

The use of two targets of different compositions, for deposition by cathode sputtering (a magnetron sputtering is not taught therein), was described in the European application EP 0 364 903 (and in the European application filed on the same day, EP 0 364 902) within the framework of the preparation of alloys based on aluminium (main element) containing Ti and Zr as other elements. In spite of generally mentioning the possibility of varying the power on the targets (in order to vary the composition of the obtained alloy), the final composition of the alloy is determined by the composition of the target. Each target consists of a pure element on which tablets of another element are placed, and it is the number of tablets adhered onto these discs which determines the proportion of the other element. In order to change the composition of the deposited alloy, the configuration of the target has therefore to be changed every time (which notably involves breakage of the vacuum and handling of the materials). In other words, the composition of the obtained alloy is determined by the configuration of the targets, which has to be changed ex situ. Moreover the targeted alloys are particular alloys rich in aluminium.

The object of the invention is to be able to produce deposits of particular alloys (amorphous alloys rich in Zr and Ti and high entropy alloys) with variable compositions (in a wide range) by only acting on the experimental deposition conditions, in particular on the power applied to the targets. Thus, the composition of the alloy may be changed without it being necessary to elaborate a new target.

The object of the invention is also the possibility of obtaining metal alloys comprising at least four elements while controlling the composition of the obtained alloys in a wide range.

The inventors have discovered surprisingly that these problems may be solved by using at least two targets consisting of several sectors comprising crystalline pure elements and/or alloyed elements and producing deposits by magnetron cathode sputtering. One of the targets may contain one or more sectors consisting of alloyed elements, the other sectors being mono-elementary. By using alloyed elements, it is possible to not multiply the number of targets and sectors making up these targets, in the case of alloys containing the largest number of elements. The alloyed elements are alloys of 2 to several elements.

Therefore the object of the invention is a process for depositing on a substrate a thin film of metal alloy comprising at least four elements, said alloy being

an amorphous alloy containing in atomic percent at least 50% of Ti and Zr elements, the Ti proportion being able to be zero; or

a high entropy alloy consisting of solid solutions, the microstructure of which contains nanocrystallites inserted in a matrix and the elements of which are selected from the group formed by Al, Co, Cr, Cu, Fe, Ni, Si, Mn, Mo, V, Zr, and Ti (these elements form the matrix and the nanocrystallites inserted in this matrix; the matrix plays the role of a continuous phase in which the nanocrystallites are dispersed); by simultaneous magnetron cathode sputtering of at least two targets which are placed in an enclosure containing a plasmagenous gas medium and at least one of which contains at least two of said alloy elements to be deposited, each of the targets being independently of each other powered by an electric power generator.

By the phrase “amorphous alloy”, is meant to designate an alloy only containing an amorphous phase or an alloy in which a few crystallites may be present in the midst of a predominant amorphous phase.

According to a first alternative of the invention, the alloy is of the “Inoue” type alloy. This alloy is an amorphous alloy containing in atomic percent at least 50% of Ti and Zr elements; Zr being the majority element and being mandatorily present whereas the Ti proportion may be zero. The elements forming the remaining portion are advantageously selected from the group consisting of Al, Co, Cr, Cu, Fe, Ni, Si, Mn, Mo and V. The particularly targeted alloy compositions are Zr_{48.5}Ti_{5.5}Al₁₁Cu₂₂Ni₁₃, Zr₅₅Cu₃₀Al₁₀Ni₅, Zr₅₅Ti₅Ni₁₀Al₁₀Cu₂₀, Zr₆₅Al_{7.5}Cu_{27.5}Ni₁₀, Zr₆₅Al_{7.5}Ni₁₀Cu_{17.5}, Zr₄₈Ti_{5.5}Cu₂₂Ni₁₃Al₇, Zr₆₀Al₁₅CO_{2.5}Ni_{7.5}Cu₁₅, Zr₅₅Cu₂₀Ni₁₀Al₁₅, in particular Zr₅₅Cu₃₀Al₁₀Ni₅.

According to a second alternative of the invention, the alloy is a high entropy alloy. A high entropy alloy is an alloy which does not contain any majority element but consists of 5-13 elements present in an equimolar amount which may range from 5% to 35%. The interest lies in that in such an alloy formation of random solid solutions are promoted relatively to the synthesis of brittle intermetallic crystalline phases. Further, it consists of nanocrystallites dispersed in an amorphous or crystalline matrix. Typically, a high entropy alloy contains at least 5 elements selected from the group consisting of Al, Co, Cr, Cu, Fe, Ni, Si, Mn, Mo, V, Zr and Ti. The particularly targeted alloy compositions are high entropy alloys with 5-13 main elements in equimolar ratios, each having an atomic percent less than 35% such as FeCoNiCrCuAlMn, FeCoNiCrCuAl_{0.5}, CuCoNiCrAlFeMoTiVZr, CuTiFeNiZr, AlTiVFeNiZr, MoTiVFeNiZr, CuTiVFeNiZrCo, AlTiVFeNiZrCo, MoTiVFeNiZrCo, CuTiVFeNiZrCoCr, AlTiVFeNiZrCoCr, MoTiVFeNiZrCoCr, AlSiTiCrFeCoNiMo_{0.5}, AlSiTiCrFeNiMo_{0.5}.

The principle of cathode sputtering is based on establishing an electric discharge between two conducting electrodes placed in an enclosure where a reduced pressure of inner gas prevails, causing the appearance at the anode of a thin film of the compound making up the antagonistic electrode.

The cathode sputtering process used is magnetron sputtering. The magnetron sputtering technique consists of confining the electrons with a magnetic field close to the target surface. By superposition of a perpendicular magnetic field to the electric field, the trajectories of the electrons wound around the magnetic field lines (cycloidal motion of the electrons around the field lines), increasing the probabilities of ionizing the gas in the vicinity of the electrode. In magnetron sputtering systems, the magnetic field increases the plasma density which has the consequence of increasing the current density on the cathode. High sputtering rates as well as a reduction in the temperature of the substrate may thereby be obtained.

In the enclosure of the reactor, the plasmagenous gas medium provides a proper sputtering yield, without inducing pollution. The plasmagenous gas medium is advantageously formed by helium, neon, argon, krypton or xenon, preferably by argon.

According to an advantageous alternative of the invention, each target is powered by an independent electric power generator capable of providing a power density comprised between 0.1 and 100 W/cm² of surface of the target, in particular between 1 and 10 W/cm².

It was seen that by varying the power of each of the magnetrons, it is possible to control the composition of the films of obtained metal alloy and of varying it in a wide range. It is also possible to vary the crystalline structure of the layers.

In addition, depending on the final composition of the desired alloy, it is possible to precede the simultaneous magnetron sputtering operation for at least two targets with a sputtering step for one of said targets or another target and/or have it be followed by the latter step.

The targets may be powered at identical or different constant electric power levels. According to an advantageous alternative of the process, during at least part of the deposition operation, at least two of said targets are powered at notably different constant electric power levels. According to an advantageous alternative of the process, during at least part of the deposition operation, at least two of said targets are powered at equal constant electric power levels.

The process may be suitable for depositing alloys having a composition gradient. With a concentration gradient of one or more elements, it is possible to ensure proper anchoring of the alloy on the substrate and/or good properties (notably anti-adhesive properties, wear resistance, corrosion resistance) at the surface. For this, the electric power supplied to at least one of the targets is variable, preferably continuously, during at least part of the duration for producing the deposit.

The process may also be suitable for depositing on a same substrate layers of alloys with different compositions. In particular, deposits alternately consisting of an alloy composition and then of another may be produced.

Conventionally, the substrate is mounted on a rotary support placed facing the targets. Said rotary support is driven with a sufficient speed of rotation so as to ensure good homogeneity of the alloy during deposition. In order to vary the composition of the alloy, it is not necessary that said rotary support be driven in translational motion.

According to an alternative of the invention, at least one of said targets only contains a single element of the alloy to be deposited (called a mono-elementary target). If need be, the mono-elementary target may consist of the element predominantly present in the desired amorphous alloy.

Within the scope of this alternative, it is possible to vary the electric power delivered by the generator powering the target only including a single element of the alloy (mono-elementary target) for at least part of the duration for producing the deposit. It is thus possible to vary the concentration of an element in the thickness of the thin film of the metal alloy.

According to an advantageous alternative of the invention, at least one of the targets has at the surface a mosaic structure containing several elements in pure and/or alloyed form, of the alloy to be deposited. All the targets may be mosaic targets.

In a mosaic structure, each of the elements is assembled in one or several areas of variable geometrical shape and these areas are grouped together in order to form the target. Each element may be grouped in a same area. The areas may optionally be superposed. Thus, the target may consist of a disc of only one of the elements in which apertures are perforated onto which other discs formed with other elements are superposed (at the apertures). The areas may also be organized as a pie (alternation of triangular areas of each of the elements forming a circular area).

Within the scope of the process according to the invention, it is also possible to use at least 3 targets for depositing the alloy layer.

The object of the invention is also a metal alloy as a thin film comprising at least four elements, capable of being deposited on a substrate by applying the process according to the invention, said alloy being:

an amorphous alloy containing in atomic percent at least 50% of Ti and Zr elements, the Ti proportion being able to be zero; or

a high entropy alloy consisting of solid solutions, the microstructure of which contains nanocrystallites inserted in a matrix and the elements of which are selected from the group consisting of Al, Co, Cr, Cu, Fe, Ni, Si, Mn, Mo, V, Zr, and Ti (these elements form the matrix and the nanocrystallites inserted in this matrix; the matrix plays the role of a continuous phase in which the nanocrystallites are dispersed).

These metal alloys exist in the amorphous state and comprise at least a nanocrystalline phase.

The phrase “amorphous alloy” is meant to designate an alloy only containing an amorphous phase or an alloy in which a few crystallites may be present in the midst of a predominant amorphous phase.

According to a first alternative of the invention, the alloy is of the “Inoue” type alloy. This alloy is an amorphous alloy containing in atomic percent at least 50% of Ti and Zr elements; Zr being the majority element and being mandatorily present whereas the Ti proportion may be zero. The elements forming the remaining portion are advantageously selected from the group consisting of Al, Co, Cr, Cu, Fe, Ni, Si, Mn, Mo and V, more advantageously from the group consisting of Al, Cu and Ni.

According to a second alternative of the invention, the alloy is an alloy with high entropy, i.e. in which there is no main or majority element. It consists of 5-13 elements present in an equimolar amount which may range from 5% to 35% which promotes formation of random solid solutions and of a microstructure containing nanocrystallites inserted in a matrix. The high entropy alloy contains at least 5 elements selected from the group consisting of Al, Co, Cr, Cu, Fe, Ni, Si, Mn, Mo, V, Zr and Ti. The selected elements have the capacity of forming together stable solid solutions.

It was seen that it was possible to obtain metal alloys which have good tribological and mechanical properties (hardness, friction coefficient, low adhesiveness, fatigue strength, resistance to abrasion, and to corrosion . . . ) and which may therefore be used in many applications.

A metal alloy may be obtained which has a homogeneous composition over the whole of its thickness. For this, the applied power on each of the targets is identical throughout the process.

Alternatively, a metal alloy may be obtained which has a concentration gradient over at least one portion of its thickness, by varying the applied power on at least one of the targets during the process.

The metal alloy may exist as successive layers of alloys with different compositions. In particular, the metal alloy may exist as a layer alternatively consisting of an alloy composition and then of another.

With the process according to the invention, metal alloys may be obtained for which the atomic percentages do not vary with the duration of the deposition (therefore the composition is independent of the deposition duration) and their thickness depends on the deposition duration.

It is then possible to obtain metal alloys which exist as a thin film, in particular a thin film with a thickness comprised between 10 nm and 10 μm, advantageously between 0.1 and 1 μm. This layer thickness range is most often sufficient for changing the surface properties.

Depending on the power applied on each of the targets, it is possible to vary the composition of the alloy and/or the crystalline structure of the layers. The applied power may also be changed during the process, by which metal alloys having a concentration gradient of at least one element or layers of alloys with different compositions may be obtained.

According to an advantageous alternative, the metal alloy exists as a layer having a concentration gradient of at least one element which increases in the vicinity of the interface with the substrate, in order to reinforce adhesion of the alloy deposited on the substrate.

According to another advantageous alternative, the metal alloy exists as a layer having a concentration gradient of at least one element between the interface and the free surface of the alloy, in order to change the adherence, hardness surface properties.

The metal alloy may be deposited on any type of substrate. In particular it is deposited on a metal or polymeric substrate.

According to the first alternative of the invention, the particularly targeted alloy compositions are metal amorphous alloys such as Zr_{48.5}Ti_{5.5}Al₁₁Cu₂₂Ni₁₃, Zr₅₅Cu₃₀Al₁₀Ni₅, Zr₅₅Ti₅Ni₁₀Al₁₀Cu₂₀, Zr₆₅Al_{7.5}Cu_{27.5}Ni₁₀, Zr₆₅Al_{7.5}Ni₁₀Cu_{17.5}, Zr_{48.5}Ti_{7.5}Cu₂₂Ni₁₃Al_{7.5}, Zr₄₁, Zr₆₀Al₁₅Co_{2.5}Ni_{7.5}Cu₁₅, Zr₅₅Cu₂₀Ni₁₀Al₁₅, in particular Zr₅₅Cu₃₀Al₁₀Ni₅.

Metal amorphous alloys generally have a smaller Young modulus than those of metals or stainless steels. The elastic zone is therefore very large in the stress domain. In a range of temperatures close to the glassy transition, these alloys have the interesting property of resuming their shape after deformation, there where all the other metals would have deformed and entered the plastic domain.

Further, metal amorphous alloys are not very sensitive to corrosion, notably because they do not have any crystallized grains, and grain boundaries through which corrosion develops in crystallized alloys.

Furthermore, because of their non-crystallized structure, metal amorphous alloys have a very low friction coefficient.

According to the second alternative of the invention, the particularly targeted alloy compositions are high entropy nanocrystalline alloys with 5-13 main elements in equimolar ratios, each having an atomic percent less than 35% such as FeCoNiCrCuAlMn, FeCoNiCrCuAl_{0.5}, CuCoNiCrAlFeMoTiVZr, CuTiFeNiZr, AlTiVFeNiZr, MoTiVFeNiZr, CuTiVFeNiZrCo, AlTiVFeNiZrCo, MoTiVFeNiZrCo, CuTiVFeNiZrCoCr, AlTiVFeNiZrCoCr, MoTiVFeNiZrCoCr, AlSiTiCrFeCoNiMo_{0.5}, AlSiTiCrFeNiMo_{0.5}.

High entropy alloys have better heat stability (their properties are not affected even after a heat treatment at 1,000° C. for 12 hours and subsequent cooling), larger hardness (larger than or equal to that of carbon steel or of quenched alloyed steel) and better corrosion resistance.

High entropy alloys, characterized by strength at higher temperatures than those of glasses, may be used in technical applications; wear, corrosion and oxidation resistances are required at high temperature.

Metal amorphous alloys and high entropy alloys consequently have beneficial applications in many fields, in particular in the field of food use coatings (release coatings) or in the automobile industry.

In an engine, the piston provides compression of fresh gases, the pressure due to combustion of the mixture and the alternating displacement. The piston consists of rings located in grooves made on the perimeter of the piston, said rings provide the seal (top compression ring, compression ring, scraper ring). Conventionally, the rings consist of soft cast iron coated with a chromium or molybdenum layer.

The amorphous metal or high entropy alloys have properties very close those of coatings already used. They have a very good resistance below the crystallization temperature, very good hardness, and are resistant to corrosion. An amorphous metal or high entropy alloy has a very low friction coefficient, thus the wear generated by friction is lesser, consequently there is less heating of the material, less friction losses, and the metal amorphous alloy has very good fatigue strength.

Deposits made by spark-erosion provide too large roughness for allowing tribological tests, deposits carried out by dipping such as for chromium are difficult to produce because it is necessary to ensure a sufficient cooling rate, further a large coating thickness would involve a higher cost price. With the process according to the invention, thin films of amorphous metal or high entropy alloy may be deposited. It is also possible to control the thickness of the deposit and thereby limit cost. Therefore it is conceivable to replace the chromium or molybdenum layer with a metal alloy layer, by which friction resistance and fatigue strength of the coated part (ring) may be improved.

Amorphous metal or high entropy alloys may also be used for coating bearings in engines. The role of the bearing is to allow proper rotation of the crankshaft. A bearing should have good mechanical strength, good conformability, good embeddability, good drag resistance, good corrosion resistance, good temperature resistance, good adherence onto the support and good heat conductivity. Amorphous metal or high entropy alloys may also find other applications in the automobile industry: camshaft, diesel injection pump, turbocharger.

The following examples are used for illustrating the invention and are non-limiting.

### CAPTION OF THE FIGURES

FIG. 1: exploded view of the mosaic target consisting of Cu, Zr, Al and Ni;

FIG. 2: linear representation of the measured (X fluorescence) element proportion depending on the ratio (Pzr+0.3Pmixed)/(Pzr+Pmixed)

Pzr corresponds to the applied power on the zirconium target, Pmixed corresponds to the applied power on the mosaic target

♦ Zr, □ Cu, Δ Ni, Al

The arrow indicates the test for which the targeted composition has been obtained;

FIG. 3: linear representation of the thickness of the layer (measured by SEM, expressed in μm) versus the total sum of the applied powers (W);

FIG. 4: diffraction diagrams obtained by X-ray diffraction of deposits No. 1, 3, 5, 9 and 7 of Example 1;

FIG. 5: atomic percent of the six elements versus the deposit number of Example 2.

FIG. 6: thickness of the coating (μm) versus the sum of the powers (W) on the three targets; Example 2

FIG. 7: X-ray diffraction diagrams of deposits 1-8 of Example 2;

FIG. 8a/8b: SEM image in a planar view (length of the white strip=500 nm)/in a cross-sectional view (length of the white strip=1 μm) of sample 8 of Example 2;

FIG. 9: Al atomic %/Cu atomic % ratio versus depth and Fe atomic %/Cu atomic % ratio versus depth, Example 3;

FIG. 10a/10b: SEM image, in a planar view (length of the white strip=500 nm)/in a cross-sectional view (length of the white strip=1 μm), of Example 3.

### EXAMPLE 1

### Metal Alloy Films of Complex Composition Obtained by Magnetron Sputtering

Metal alloy films of the family Zr—Cu—Al—Ni were produced by plasma sputtering of mosaic targets. The targeted composition was Zr₅₅Cu₃₀Al₁₀Ni₅. In the calculation of the area which each chemical element should occupy in order to result in this composition (equation (1)), the sputtering rate with argon ions (plasmagenous gas used during the sputtering) of about 300 eV was taken into account. This is shown in Table 1 below:

TABLE 1

| | Targeted | Theoretical | Proportion of |
|---|---|---|---|
| Element | composition | sputtering rate | the total surface |
| Zr | 55% | 0.3 | 77.6% |
| Cu | 30% | 1 | 12.7% |
| Al | 10% | 0.6 | 7.1% |
| Ni | 5% | 0.8 | 2.6% |

Two targets are used: one totally consisting of Zr, a majority element at low sputtering rate, and another one, a mosaic target, containing the four elements in the following proportions: Cu: 56.9%, Zr: 30.4%, Al: 8.9%, Ni: 3.8%. In order to obtain a good electric contact and to optimize the attachment of each piece, a slightly peculiar geometry was contemplated: pieces of Zr, Al and Ni plates are placed under a Cu disc perforated with holes (cf. FIG. 1). Indeed, it was seen that the use of a target consisting of juxtaposed pie-shaped pieces was not suitable because the medium did not remain in contact after sputtering.

The targets are discs of diameter 10 cm and with a thickness of a few mm.

The theoretical amount of zirconium on the 2^{nd} target is so large, that it would cause unbalance of the whole of the target. A geometrically balanced target is therefore selected which does not observe the theoretically calculated percentages. The mixed target thus has more copper and less zirconium than the theoretical ideal target.

### Deposition Procedure

The targets are cleaned with acetone and then with alcohol after machining and then attached onto the magnetrons placed at 30° relatively to the normal to the substrate.

For this first series of depositions, silicon wafers (100) (covered with native oxide) were selected as substrates. They are cut out (1.5*1.5 cm²), cleaned and adhesively bonded onto the sample holder in the reactor via an airlock. Argon is introduced at a pressure of 0.21 Pa (2.1×10⁻³ mb). Before each deposition, the targets are pre-sputtered for 4 min in order to remove possible residual oxidation. During the deposition, the substrate is set into rotation (about 1 turn in 20 s) in order to ensure good homogeneity of the composition in the plane. (2-20 min) deposits are accomplished. The powers imposed to each magnetron are independent, they were varied from (110 to 520) W which corresponds to voltages on the targets of (110 to 390)V and currents of (0.4 to 1.7) A. On this type of magnetron, when the power is set, voltage and current are then automatically adjusted for observing the set power value.

Table 2 hereafter gives the various accomplished depositions.

TABLE 2

| | Power on the | Power on the | |
|---|---|---|---|
| | Zr target | mixed target | Deposition |
| Deposit No. | (Pzr in W) | (Pmixed in W) | time (min) |
| 1 | 520 | 520 | 2 |
| 2 | 520 | 520 | 10 |
| 3 | 520 | 520 | 20 |
| 4 | 320 | 520 | 2 |
| 5 | 320 | 520 | 20 |
| 6 | 110 | 520 | 2 |
| 7 | 110 | 520 | 20 |
| 8 | 520 | 320 | 2 |
| 9 | 520 | 320 | 20 |
| 10 | 230 | 520 | 20 |
| 11 | 520 | 410 | 20 |
| 12 | 320 | 250 | 9′30 |

### Results

Determination of the composition was carried out by X-ray analysis (Energy Dispersive Spectroscopy (EDS)) during scanning electron microscopy (SEM) observations on the thickest deposits (20 min).

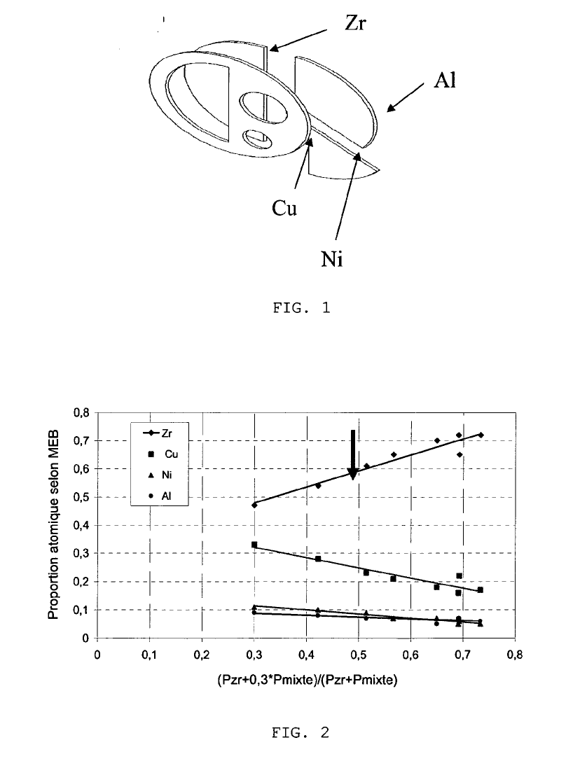

The results are given in FIG. 2 where the measured Zr proportion is plotted versus the (Pzr+0.3Pmixed)/(Pzr+Pmixed) ratio since about 30% of the mosaic target consists of Zr. For facilitating comparison with the other elements, the same unit is used while their proportion is especially related to Pmixed.

By imposing the same power on both targets, the targeted composition is not obtained.

It is seen that the proportion of the different elements of the alloy is directly determined by the powers applied to both targets. This is clearly visible on the majority elements Zr and Cu. It is therefore possible to start from an empirical curve of this type in order to determine the powers to be used for obtaining a given composition. Further it is interesting to see that the Zr percentage was able to be changed in a wide range, from 47% to 72%. Thus the targeted composition (55% Zr) has practically be attained for a sample (No. 7) marked by an arrow in FIG. 2.

The results of an EDS analysis carried out on deposits No. 2 and 3 are also given in the following Table 3:

TABLE 3
EDS analysis carried out on deposits No. 2 and 3

| Elements | Atomic % of deposit No. 2 | Atomic % of deposit No. 3 |
|---|---|---|
| Al | 5.06 | 5.10 |
| Ni | 6.78 | 6.97 |
| Cu | 18.55 | 17.95 |
| Zr | 69.60 | 69.98 |

It is seen that the atomic percentages do not vary with the duration of the deposition, consequently the composition is independent of the deposition duration.

EDS analyses were carried out on different portions of the deposit NO. 3. The obtained percentages on the different portions are almost similar with an uncertainty of 1%, which means that the obtained deposit is homogenous.

The results of an EDS analysis carried out on the deposits No. 3, 5, 7 and 9 are also given in Table IV below:

TABLE 4
EDS analysis carried out on deposits No. 3, 5, 7 and 9

| | Atomic % of | Atomic % of | Atomic % of | Atomic % of |
|---|---|---|---|---|
| | deposit | deposit | deposit | deposit |
| Elements | No. 3 | No. 5 | No. 7 | No. 9 |
| Al | 5.10 | 6.07 | 8.29 | 6.04 |
| Ni | 6.97 | 7.21 | 9.93 | 4.51 |
| Cu | 17.95 | 21.00 | 28.10 | 17.34 |
| Zr | 69.98 | 65.09 | 53.69 | 72.12 |

The results on four 20 min deposits show that the composition of the alloy varies with the applied power on the targets. By acting on the applied powers, it is thereby possible to obtain a metal alloy very close to the targeted composition (deposit No. 7).

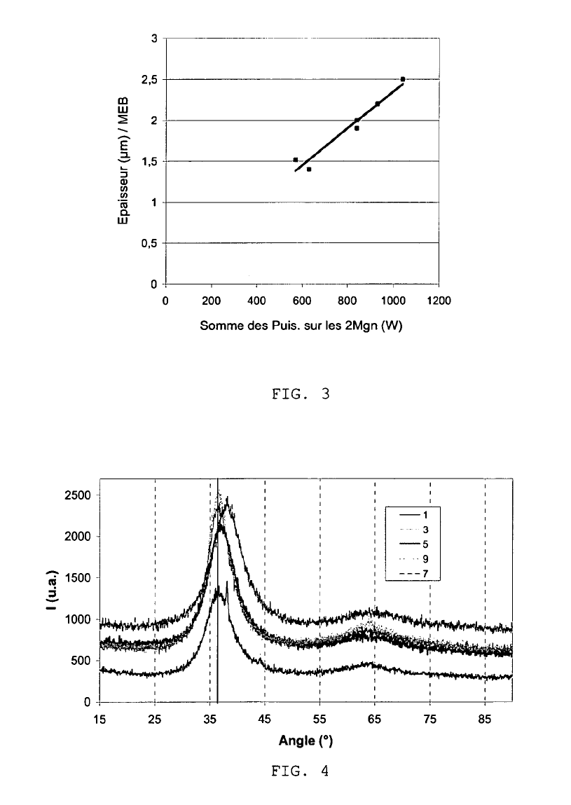

The thickness of the 20 min deposit was measured with SEM on sectional views. It directly depends on the total sum of the applied powers on the targets as shown by the graph of FIG. 3. The obtained deposition rates are relatively high from 70 nm/min to 120 nm/min with which thick films may be produced in a reasonable time.

The crystalline structure of the deposits was investigated by X-ray diffraction at grazing incidence in order to enhance the signal from the film relatively to the substrate. The obtained diffraction diagrams have one or two wide characteristic peaks of an amorphous or nanocrystalline phase (FIG. 4).

A crystal diffracts X-rays according to Bragg's law:

2dₕₖₗ sin θ=nλ.

Thus the more the material is crystallized the more the peaks will be sharp. Very large peaks will imply that our deposits are amorphous.

Regardless of the composition, in the investigated range, the deposits from sputtering of crystalline elements, are not crystallized.

Transmission electron microscopy analysis was also carried out in order to determine whether nanocrystals are present in the structure or not. The first tests show that the formed film is amorphous and non-crystalline.

SEM observations of the surface of the deposits were conducted. Most films have nodules which are always enriched with Al, the density of which seems to be related to the conditions for obtaining them. It seems that the number of these nodules increases with the deposition time but no simple correlation seems to exist with the powers of the magnetrons. The largest (from one μm to a few hundreds of nm) are subdivided into small entities, this is not the case for the smallest nodules. The origin of the formation of these nodules is not well understood, however it seems to be characteristic of the deposits when there are produced from crystallized mosaic targets. Indeed, films of the same alloys obtained from an alloy target by the same deposition process do not show these structures at the surface.

### EXAMPLE 2

### High Entropy Metal Alloy Films Obtained by Magnetron Sputtering

Metal alloy films of the family Al—Co—Cr—Cu—Fe—Ni were produced by plasma sputtering of mosaic targets. The targeted composition was AlCoCrCuFeNi. In the calculation of the area which each chemical element should occupy in order to result in this composition (equation (1)), the sputtering rate with argon ions (plasmagenous gas used during sputtering) of about 300 eV was taken into account. This is shown in Table 5 below.

TABLE 5
sputtering rate

| | Targeted | Theoretical | Proportion of |
|---|---|---|---|
| Element | composition | sputtering rate | the total surface |
| Al | 16.67% | 0.62 | 20 |
| Co | 16.67% | 0.8 | 15.6 |
| Cr | 16.67% | 0.75 | 16.6 |
| Cu | 16.67% | 1.18 | 10.5 |
| Fe | 16.67% | 0.6 | 20.7 |
| Ni | 16.67% | 0.75 | 16.6 |

Three targets are used: one totally consisting of Al (target 1) another one, a mosaic target, containing Cu and Cr elements in the following surface proportions: Cu: 39%; Cr: 61% (target 2) and a third one consisting of the magnetic elements: Co, Fe and Ni in the following surface proportions: Co: 29.5%, Fe: 39% and Ni: 31.5% (target 3). The geometry of the targets is the one used in Example 1: pieces of Co and Ni plates are placed under a Fe disc perforated with holes for target 3. Cu and Cr half-discs are stacked in order to allow easier adjustment of stoichiometry (target 2). The targets are discs with diameter of 10 cm and a thickness of a few mm.

### Deposition Procedure

The targets are cleaned with acetone and then with alcohol after machining on magnetrons placed at 30° relatively to the normal to the substrate.

The imposed powers at each magnetron vary from (12 to 558) W which corresponds to voltages on the targets from (298 to 465)V and of currents from (0.04 to 1.2) A.

The deposition procedure remains unchanged with respect to Example 1, only the speed of rotation of the substrate is changed (1 turn in 5 s) and also the deposition time (25 min).

Table 6 hereafter gives the different depositions carried out.

TABLE 6

| | Power on the | Power on the | Power on the |
|---|---|---|---|
| Deposition | Al target 1 | CuCr target | FeCoNi target |
| No. | (P1 in W) | 2 (P1902 in W) | 3 (P3 in W) |
| 1 | 18 | 190 | 170 |
| 2 | 27 | 110 | 180 |
| 3 | 12 | 300 | 180 |
| 4 | 21 | 180 | 100 |
| 5 | 15 | 180 | 310 |
| 6 | 362 | 180 | 160 |
| 7 | 501 | 180 | 160 |
| 8 | 147 | 180 | 310 |

### Results

Determination of the composition was made by X analysis (Energy Dispersive Spectroscopy) during scanning electron microscopy observations (MEB).

The results of these analyses are reported in Table 7 and FIG. 5.

TABLE 7
EDS analysis carried out on depositions Nos. 1-8

| | |
|---|---|
| Deposition | Atomic % of the elements |

| No. | Al | Co | Cr | Cu | Fe | Ni |
|---|---|---|---|---|---|---|
| 1 | 13 | 14 | 27 | 11 | 16 | 19 |
| 2 | 17 | 17 | 18 | 8 | 17 | 23 |
| 3 | 10 | 10 | 36 | 17 | 11 | 16 |
| 4 | 17 | 11 | 33 | 16 | 11 | 12 |
| 5 | 10 | 17 | 18 | 9 | 22 | 24 |
| 6 | 42 | 11 | 17 | 6 | 11 | 13 |
| 7 | 33 | 13 | 20 | 9 | 10 | 15 |
| 8 | 24 | 15 | 15 | 7 | 19 | 20 |

Uncertainty on these values is ±1%.

FIG. 5 illustrates the atomic % of the six elements versus the deposition number. The atomic area between 5 and 35% corresponds to the definition domain of high entropy alloys.

The results on eight 25 min deposits show that the composition of the alloy varies depending on the applied power on the targets. By acting on the applied powers, it is thus possible to obtain a metal alloy very close to the targeted composition (deposit No. 2 or 6). High entropy alloys have a definition domain comprised between 5 and 35% atomic concentration of each element. A large range of compounds may thereby be obtained. Here, AlCoCrCuFeNi was selected, it is seen that on the eight deposits, six meet this criterion.

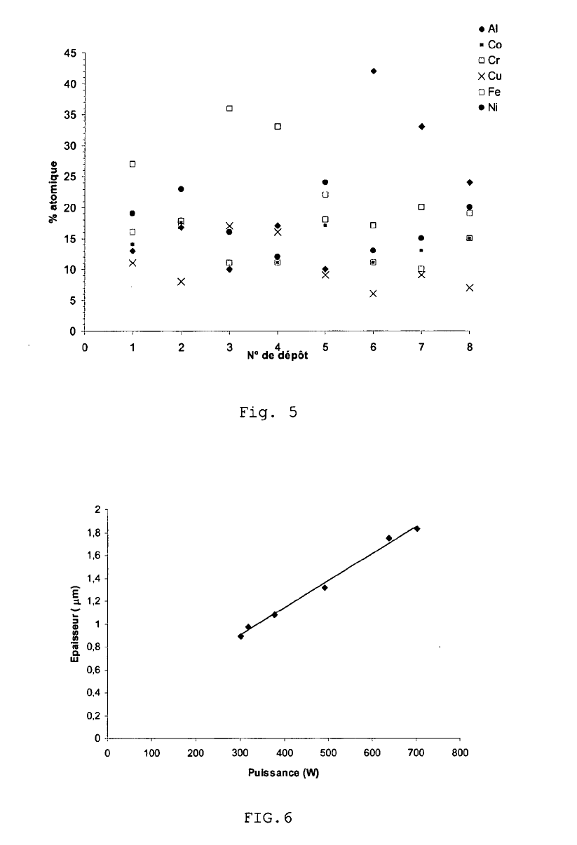

The thickness of the 25 min deposits was measured on the SEM on sectional views. It directly depends on the total sum of the applied powers on the targets as shown by the graph in FIG. 6. The obtained deposition rates are relatively high from 36 nm/min to 90 nm/min, with which thick films may be produced in a reasonable time.

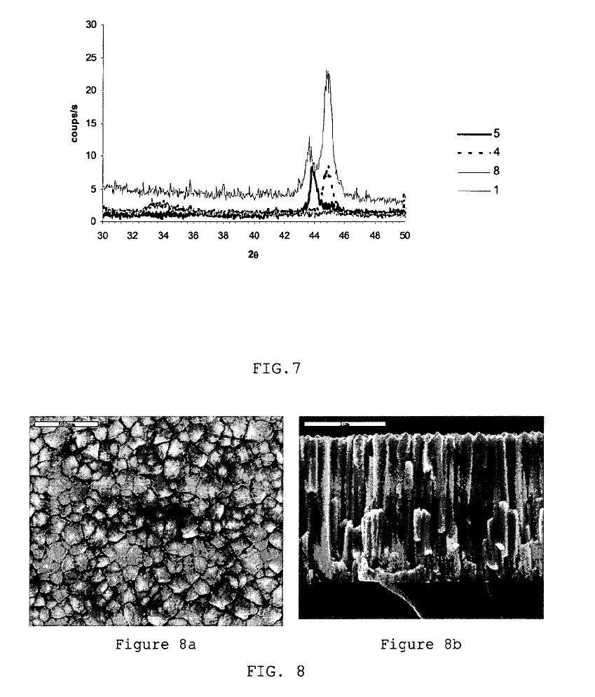

The crystalline structure of the deposits has been studied by X-ray diffraction. The obtained diffraction diagrams show one or two wide peaks characteristic of an amorphous or crystalline phase (FIG. 7). A FCC structure (face centred cubic) is assigned to the layers having a peak at 2θ=43.6° and a BCC structure (body centred cubic) is assigned to layers having a peak at 2θ=44.6°. Layer 1 has two structures, layer 4 has a BCC structure, layer 5 has a FCC structure and layer 8 does not have any BCC or FCC structure, it only has a hump at 2θ=33.9° characteristic of an amorphous structure. These diffraction diagrams comply with those found in the literature on this same alloy (J-W. Yeh, Materials Chemistry and Physics, 2007) and show that with the applied powers on the targets, it is possible in addition to modifying the composition, to act on the crystalline structure of the layers. Regardless of the composition, in the investigated range, deposits from sputtering of crystalline elements are not very crystallized.

The cross-sectional SEM images confirm the nanocrystalline structure of the layers (FIGS. 8a and 8b). The size of the grains varies from tens to about a hundred nanometres.

### EXAMPLE 3

### High Entropy Metal Alloy Film Having a Concentration Gradient Obtained by Magnetron Sputtering

Metal alloy films of the family of Al—Co—Cr—Cu—Fe—Ni were produced by plasma sputtering of mosaic targets. The targeted composition was AlₓCoCrCuFeNi. In one of the films, the concentration of the element Al was varied in the thickness of the layer while keeping constant the atomic concentrations of the other elements. For this, the configuration of the targets of Example 2 was again taken in the same way and the power was varied on the aluminium target. The aluminium target (target 1) being mono-elementary, by changing the applied power, it is possible to vary the stoichiometry in the film.

### Deposition Procedure

The targets are cleaned with acetone and then with alcohol after machining and then placed on magnetrons placed at 30° relatively to the normal to the substrate.

The deposition procedure remains unchanged with respect to Example 1, only the speed of rotation of the substrate is changed (1 turn in 5 s) and the deposition time set to 25 min. The imposed powers on the magnetrons 2 and 3 are set to 558 W and 210 W respectively, which corresponds to voltages on the targets of 465 and 467 V and currents of 1.2 and 0.35 A respectively. The power on the aluminium target varies from 0 to 580 W from the interface to the surface, which corresponds to a voltage comprised between 0 and 736 V and a current between 0 and 0.79 A.

### Results

Determination of the composition was made by X-ray analysis (Energy Dispersive Spectroscopy) during scanning electron microscopy (SEM) observations. The results are given in FIG. 9 where the ratio is reported in atomic percentage of aluminium on copper and the atomic ratio of iron on copper.

It is seen that the copper concentration relatively to iron remains constant during deposition, which was expected, and that the aluminium proportion increases with thickness or time. The effect of the ramp on the aluminium target is therefore actually present. The concentration of the other elements actually remained constant during deposition. By acting on the applied powers, it is thus possible to obtain a metal alloy having a concentration gradient. This concentration gradient may also be produced for several elements, the powers are then varied on several targets.

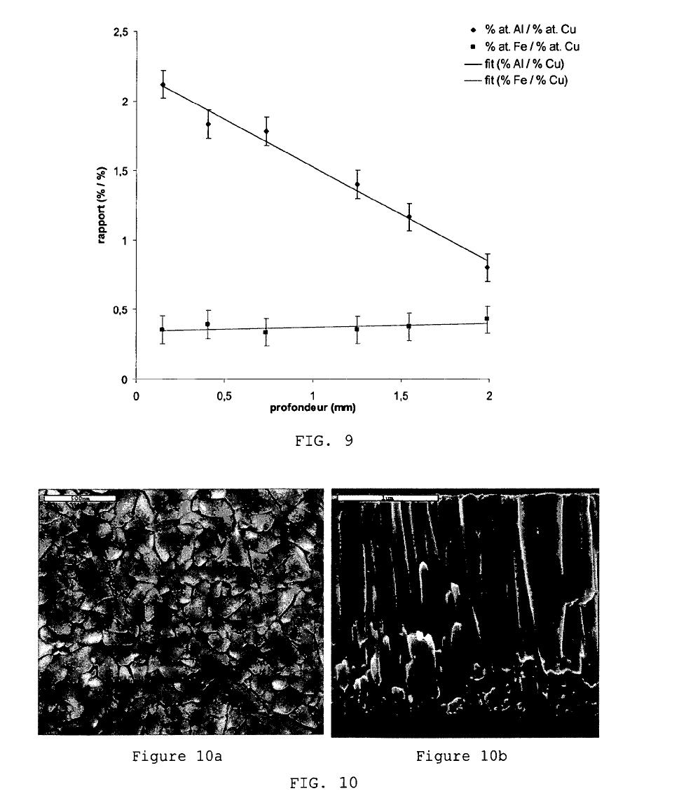

The SEM planar and cross-sectional images show a nanocrystalline structure similar to the deposits of Example 2. (FIGS. 10a and 10b).

1. A process for depositing on a substrate a thin film of metal alloy comprising at least four elements, said alloy being:
an amorphous alloy containing in atomic percent at least 50% of Ti and Zr elements, the Ti proportion being able to be zero; or
a high entropy alloy consisting of solid solutions, the microstructure of which contains nanocrystallites inserted in a matrix and the elements of which are selected from the group formed by Al, Co, Cr, Cu, Fe, Ni, Si, Mn, Mo, V, Zr, and Ti
by simultaneous magnetron cathode sputtering of at least two targets which are placed in an enclosure containing a plasmagenous gas medium and at least one of which contains at least two of said alloy elements to be deposited, each of the targets being independently of each other powered by an electric power generator.

2. The process according to claim 1, characterized in that the plasmagenous gas medium is formed by helium, neon, argon, krypton or xenon.

3. The process according to claim 1, characterized in that each target is powered by an independent electric power generator, capable of providing a power comprised between 0.1 and 100 W/cm² of surface of the target.

4. The process according to claim 1, characterized in that the simultaneous magnetron sputtering operation of at least two targets is preceded and/or followed by a magnetron sputtering step for one said targets or for another target.

5. The process according to claim 1, characterized in that, during at least part of the deposition operation, at least two of said targets are powered at notably different electric power constant levels.

6. The process according to claim 1, characterized in that during at least part of the deposition operation, at least two of said targets are powered at equal electric power constant levels.

7. The process according to claim 1, characterized in that electric power powering at least one of the targets is variable, preferably continuously, during at least part of the deposition operation.

8. The process according to claim 1, characterized in that the substrate is mounted on a rotary support placed facing the targets and driven at a sufficient speed of rotation in order to ensure good homogeneity of the alloy during the deposition.

9. The process according to claim 1, characterized in that at least one of said targets only contains a single element of the alloy to be deposited.

10. The process according to claim 9, characterized in that the electric power delivered by the generator powering the target only including a single element of the alloy is variable for at least part of the duration for producing the deposit.

11. The process according to claim 1, characterized in that at least three targets are used for depositing the alloy layer.

12. The process according to claim 1, characterized in that one of the targets has at the surface a mosaic structure containing several elements either in pure or alloyed form, of the alloy to be deposited.

13. A metal alloy as a thin film comprising at least four elements, capable of being deposited on a substrate by applying the process according to claim 1; said alloy being
an amorphous alloy containing in atomic percent at least 50% of Ti and Zr elements, the Ti proportion being able to be zero; or
a high entropy alloy consisting of solid solutions, the microstructure of which contains nanocrystallites inserted in a matrix and the elements of which are selected from the group consisting of Al, Co, Cr, Cu, Fe, Ni, Si, Mn, Mo, V, Zr, and Ti.

14. The metal alloy according to claim 13, characterized in that it is in the amorphous state and contains in atomic percent 50% of the Ti and Zr elements, the Ti proportion being able to be zero, the other elements being selected from the group formed by Al, Co, Cr, Cu, Fe, Ni, Si, Mn, Mo and V.

15. The metal alloy according to claim 13, characterized in that it has good tribological and mechanical properties.

16. The metal alloy according to claim 13, characterized by a homogeneous composition over the whole of its thickness.

17. The metal alloy according to claim 13, characterized in that it has a concentration gradient over at least part of its thickness.

18. The metal alloy according to claim 13, characterized in that it exists as successive layers of alloys with different compositions.

19. The metal alloy according to claim 13, characterized in that it exists as a thin film with a thickness comprised between 10 nm and 10 μm.

20. The metal alloy according to claim 13, characterized in that it exists as a layer having a concentration gradient of at least one element which increases in the vicinity of the interface with the substrate, for reinforcing adhesion of the alloy deposited on the substrate.

21. The metal alloy according to claim 13, characterized in that it is in the form of a layer having a concentration gradient of at least one element between the interface and the free surface of the alloy, in order to change the anti-adhesive surface properties, hardness properties.

22. The metal alloy according to claim 13, characterized in that it is deposited on a metal or polymeric substrate.

23. A metal alloy as a thin film comprising at least four elements, said alloy being
an amorphous alloy containing in atomic percent at least 50% of Ti and Zr elements, the Ti proportion being able to be zero; or
a high entropy alloy consisting of solid solutions, the microstructure of which contains nanocrystallites inserted in a matrix and the elements of which are selected from the group consisting of Al, Co, Cr, Cu, Fe, Ni, Si, Mn, Mo, V, Zr, and Ti.
